(19) United States
(12) Patent Application Publication
(10) Pub. No.: US 2018/0288891 A1
(43) Pub. Date: Oct. 4, 2018

(54) Hinge and electronic device using the same

(71) Applicant: SHIN ZU SHING CO., LTD., New Taipei City (TW)

(72) Inventors: Ting-Hsien WANG, New Taipei City (TW); Ya-Chen TSENG, New Taipei City (TW); Po-Hua CHU, New Taipei City (TW); Wei-Ting KUO, New Taipei City (TW); Chun-Chi SU, New Taipei City (TW); Tsung-Yu YANG, New Taipei City (TW)

(21) Appl. No.: 15/475,474

(22) Filed: Mar. 31, 2017

(51) Int. Cl. H05K 5/02; F16C 11/04; E05D 7/00

(52) U.S. Cl. CPC H05K 5/0226; E05Y 2900/606; E05D 7/00; F16C 11/04

(57) ABSTRACT

A hinge and an electronic device using the same are disclosed. The hinge includes a fixing member, a shaft member, and a spring member. The fixing member includes a pivoting portion and a fixing portion. The pivoting portion and the fixing portion are respectively fixed to opposite ends of the fixing member. The shaft member is pivotably connected to the pivoting portion. The spring member includes a spring body, a first end, and a second end. The spring body is between the first end and the second end. The first end is fixed to the shaft member. The second end is fixed to the fixing portion. When the shaft member rotates, the shaft member drives the spring body to twist via the first end.

### FIELD OF THE INVENTION

The present invention relates to an electronic device and, more particularly, to a hinge and an electronic device using the same.

### BACKGROUND OF THE INVENTION

Modern electronic devices, especially portable electronic devices, are getting lighter, thinner, and smaller. Some of the portable electronic devices, e.g., a hand-held game console or a small size laptop computer, are foldable. In general, a portable electronic device which is foldable includes two plates pivotably connected to each other. A display is disposed on one of the plates, and components such as a processor and a driving module are disposed in the other one of the plates.

Conventionally, a hinge can be utilized for having the two plates of the electronic device be pivotably connected to each other. The structure of a typical hinge is complicated and thus causes the cost of manufacture of a whole product to inevitably increase. In addition, the typical hinge is of a straight shape. If an electronic device has a special appearance, e.g., two sides of the electronic device are of an arc shape, the straight hinge may be hard to be installed in the electronic device. The use of conventional hinges is limited.

### SUMMARY OF THE INVENTION

To address the above issue, the present invention provides a hinge and an electronic device using the hinge, which aims to lower the cost of manufacture of the hinge and the electronic device. Additionally, the hinge can be utilized in electronic devices with special appearance.

According to an embodiment of the present invention, a hinge comprises a fixing member, a shaft member, and a spring member. The fixing member comprises a pivoting portion and a fixing portion. The pivoting portion and the fixing portion are respectively fixed to opposite ends of the fixing member. The shaft member is pivotably connected to the pivoting portion. The spring member comprises a spring body, a first end, and a second end. The spring body is between the first end and the second end. The first end is fixed to the shaft member. The second end is fixed to the fixing portion. When the shaft member rotates, the shaft member drives the spring body to twist via the first end.

According to an embodiment of the present invention, the spring body is of an arc shape.

Additionally, the fixing member further comprises an arc plate. The pivoting portion and the fixing portion are respectively fixed to opposite ends of the arc plate. The spring body is disposed corresponding to the arc plate.

According to an embodiment of the present invention, the shaft member comprises a bracket portion. The bracket portion is coupled to an end of the shaft member, and the first end is fixed to the bracket portion.

Additionally, the bracket portion comprises a first fixing column. The first fixing column penetrates into the first end. The first end surrounds and is fixed to the first fixing column. Moreover, the bracket portion comprises an embedding hole. The embedding hole has a non-circular cross section. An end of the shaft member fits and is fixed in the embedding hole. Further, the pivoting portion comprises an axial hole. The shaft member is rotatably disposed in the axial hole. The bracket portion is between the spring body and the pivoting portion.

According to an embodiment of the present invention, the fixing portion comprises a second fixing column. The second fixing column penetrates into the second end. The second end surrounds and is fixed to the second fixing column.

According to an embodiment of the present invention, an electronic device comprises an aforementioned hinge, a first plate, and a second plate. The shaft member of the hinge is fixed to the first plate. The fixing member of the hinge is fixed to the second plate.

According to an embodiment of the present invention, an edge of the second plate is of an arc shape. The spring body is disposed corresponding to the arc-shaped edge.

Concisely, the present invention provides a hinge and an electronic device using the hinge. The hinge has a simple structure, which can lower the cost of manufacture of the hinge and the electronic device. Additionally, the hinge has better adaptability; therefore, the hinge can be utilized in electronic devices with special appearance, e.g., an electronic device with an arc-shaped edge.

The features of the present invention will no doubt become understandable to those of ordinary skill in the art after reading the following detailed description of the preferred embodiment that is illustrated in the various figures and drawings.

### BRIEF DESCRIPTION OF THE DRAWINGS

FIG. 1 illustrates a perspective view of an electronic device according to an embodiment of the present invention; FIG. 2 illustrates a perspective view of the electronic device of FIG. 1 from another viewing angle according to an embodiment of the present invention;

FIG. 3 illustrates a perspective view of a second plate and a hinge according to an embodiment of the present invention;

FIG. 4 illustrates a perspective view of the hinge according to an embodiment of the present invention;

FIG. 5 illustrates an exploded view of the hinge according to an embodiment of the present invention; and

FIG. 6 illustrates an exploded view of the hinge of FIG. 5 from another viewing angle according to an embodiment of the present invention.

### DETAILED DESCRIPTION OF ILLUSTRATIVE EMBODIMENTS

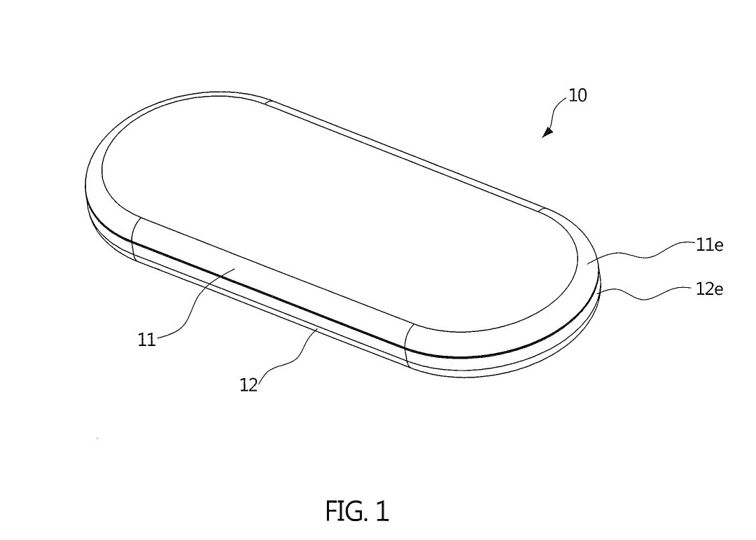

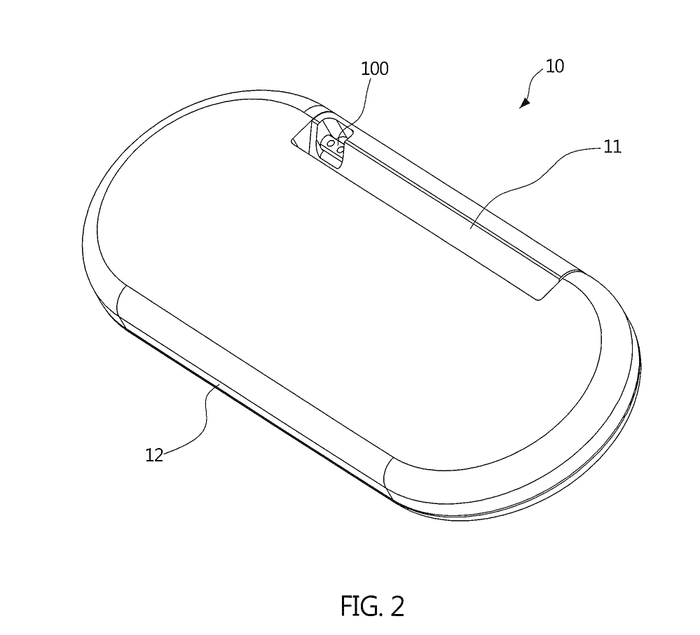

Referring to FIG. 1 and FIG. 2, FIG. 1 illustrates a perspective view of an electronic device 10 according to an embodiment of the present invention. FIG. 2 illustrates a perspective view of the electronic device 10 of FIG. 1 from another viewing angle according to an embodiment of the present invention. In the embodiment, the electronic device 10 is, but is not limited to, a portable, hand-held game console. The electronic device 10 comprises a first plate 11 and a second plate 12. The first plate 11 and the second plate 12 are pivotably connected to each other. The first plate 11 and the second plate 12 can be spread relatively or the first plate 11 and the second plate 12 can be closed relatively. Edges 11e, 12eof the first plate 11 and the second plate 12 are of an arc shape.

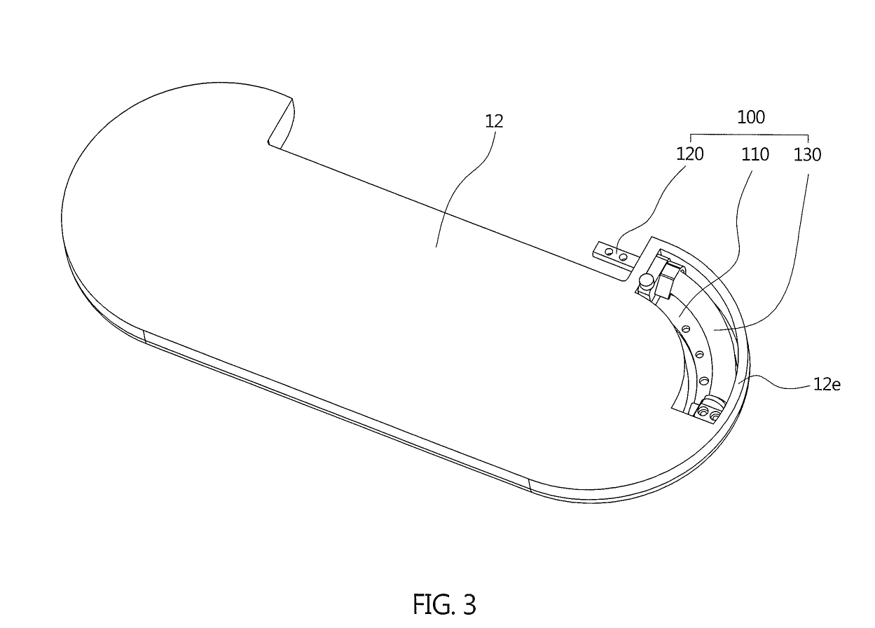

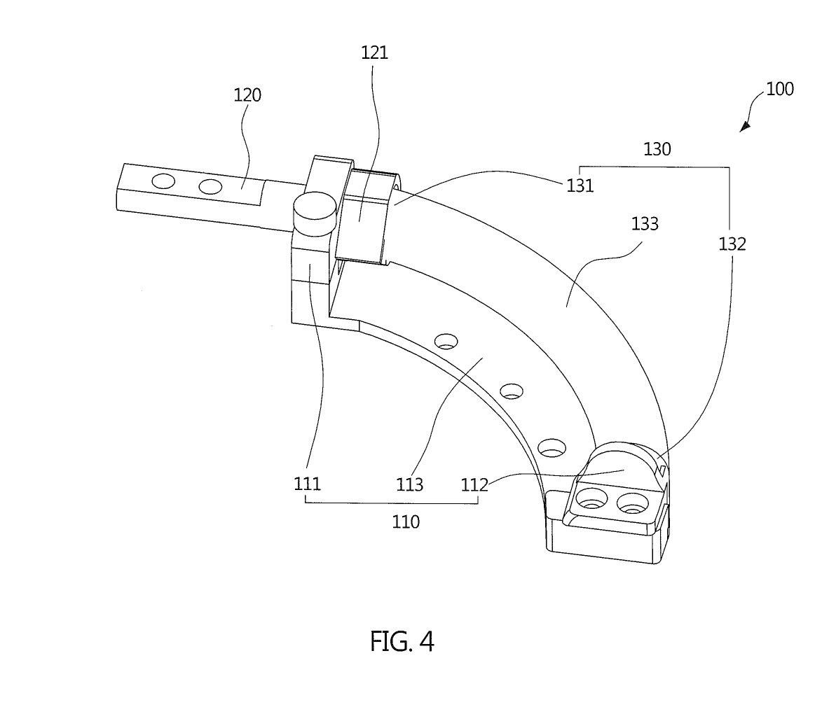

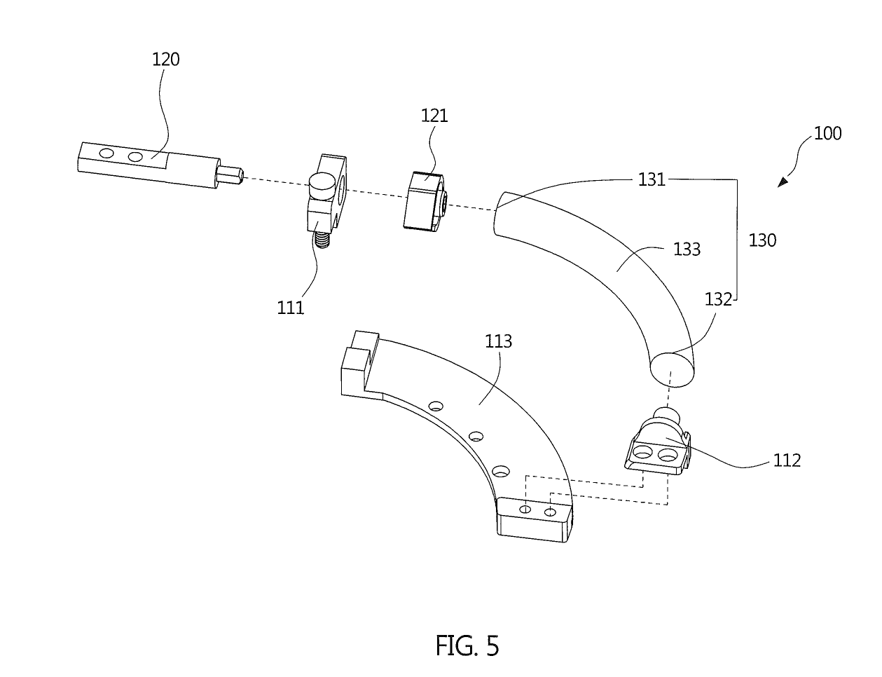

Please refer to FIG. 3 to FIG. 5. FIG. 3 illustrates a perspective view of the second plate 12 and a hinge 100 according to an embodiment of the present invention. FIG. 4 illustrates a perspective view of the hinge 100 according to an embodiment of the present invention. FIG. 5 illustrates an exploded view of the hinge 100 according to an embodiment of the present invention. The electronic device 10 further comprises the hinge 100. The first plate 11 and the second plate 12 are pivotably connected to each other via the hinge 100. The first plate 11 may, for example, have a display disposed thereon. The second plate 12 may, for example, have a processor and a driving module disposed therein. Electronic components in the first plate 11 and electronic components in the second plate 12 are electrically connected to one another. When a user needs to use the electronic device 10, the user can pull the first plate 11 and the second plate 12 which are in a closed state in the first place to have the first plate 11 rotate about the hinge 100 relative to the second plate 12 until the first plate 11 and the second plate 12 are spread relatively at an appropriate angle. In the meantime, the hinge 100 generates an appropriate torsion described as follows.

In the embodiment, the hinge 100 comprises a fixing member 110, a shaft member 120, and a spring member 130. The fixing member 110 comprises a pivoting portion 111 and a fixing portion 112. The pivoting portion 111 and the fixing portion 112 are respectively fixed to opposite ends of the fixing member 110. In the embodiment, the pivoting portion 111 is, but is not limited to, adjacent to a side wall of the second plate 12. In other embodiment, the pivoting portion 111 may also be a part of the side wall of the second plate 12. The shaft member 120 rotatably penetrates through the side wall of the second plate 12 and is further pivotably connected to the pivoting portion 111. Specifically, the shaft member 120 penetrates through the pivoting portion 111 along an axle and is disposed on the pivoting portion 111. The shaft member 120 is able to rotate about the axle relative to the pivoting portion 111. In the embodiment, the shaft member 120 comprises a bracket portion 121. The bracket portion 121 is coupled to an end of the shaft member 120. In the embodiment, the spring member 130 comprises a first end 131, a second end 132, and a spring body 133. The spring body 133 is between the first end 131 and the second end 132. The first end 131 is fixed to the bracket portion 121 of the shaft member 120. The second end 132 is fixed to the fixing portion 112. In other words, when the shaft member 120 rotates, the shaft member 120 drives the spring body 133 to rotate via the first end 131; however, the second end 132 of the spring member 130 is stationary relative to the first end 131 and is unable to rotate, and, consequently, the spring body 133 driven by the shaft member 120 is going to twist.

In the embodiment, the shaft member 120 of the hinge 100 is fixed to the first plate 11, and the fixing member 110 of the hinge 100 is fixed to the second plate 12. When a user pulls the first plate 11 and the second plate 12 which are in the closed state in the first place in order to have the first plate 11 and the second plate 12 spread relatively, the first plate 11 rotates about the hinge 100 relative to the second plate 12, and the shaft member 120 rotates along with the first plate 11 and drives the spring body 133 to twist via the first end 131. Additionally, the spring body 133 generates less torsion when the first plate 11 and the second plate 12 are closed relatively, and the spring body 133 generates greater torsion when the first plate 11 and the second plate 12 are spread relatively to cause the spring body 133 to twist. The twisting angle of the spring body 133 increases, and the torsion generated by the spring body 133 accordingly increases along with the increasing of the angle between the first plate 11 and the second plate 12 when the first plate 11 and the second plate 12 are being spread. In such configuration, the first plate 11 and the second plate 12 of the electronic device 10 are tend to keep in the closed state because it requires greater torsion to make the first plate 11 and the second plate 12 spread.

In other embodiments, when a user pulls the first plate 11 and the second plate 12 which are in the spread state in the first place in order to have the first plate 11 and the second plate 12 closed relatively, the first plate 11 rotates about the hinge 100 relative to the second plate 12, and the shaft member 120 rotates along with the first plate 11 and drives the spring body 133 to twist via the first end 131. Additionally, the spring body 133 generates the least torsion when the first plate 11 and the second plate 12 are spread relatively at a predetermined angle, e.g., 180 degrees. Under the circumstances, the spring body 133 generates greater torsion due to the twisting spring body 133 when the first plate 11 and the second plate 12 are being closed relatively. The twisting angle of the spring body 133 increases, and the torsion generated by the spring body 133 accordingly increases along with the decreasing of the angle between the first plate 11 and the second plate 12 when the first plate 11 and the second plate 12 are being closed. In such configuration, the first plate 11 and the second plate 12 of the electronic device 10 are tend to keep in the spread state because it requires greater torsion to make the first plate 11 and the second plate 12 closed.

In the embodiment, because the edges 11e, 12eof the first plate 11 and the second plate 12 are of an arc shape, and the electronic device 10 is small, the spring body 133 is disposed corresponding to the arc-shaped edges 11 e, 12esuch that the hinge 100 can be properly received in the electronic device 10. That is to say, the spring body 133 is corresponding to the edges 11e, 12eof the first plate 11 and the second plate 12 to form the arc shape and is disposed adjacent to the edge 12eof the second plate 12. Additionally, the fixing member 110 further comprises an arc plate 113. The pivoting portion 111 and the fixing portion 112 are respectively fixed to opposite ends of the arc plate 113. The arc plate 113 is also corresponding to the edges 11e, 12eof the first plate 11 and the second plate 12 to form the arc shape, and the spring body 133 is disposed corresponding to the arc plate 113. In other embodiments, the spring body 133 can form other shapes such as a straight shape or an L shape.

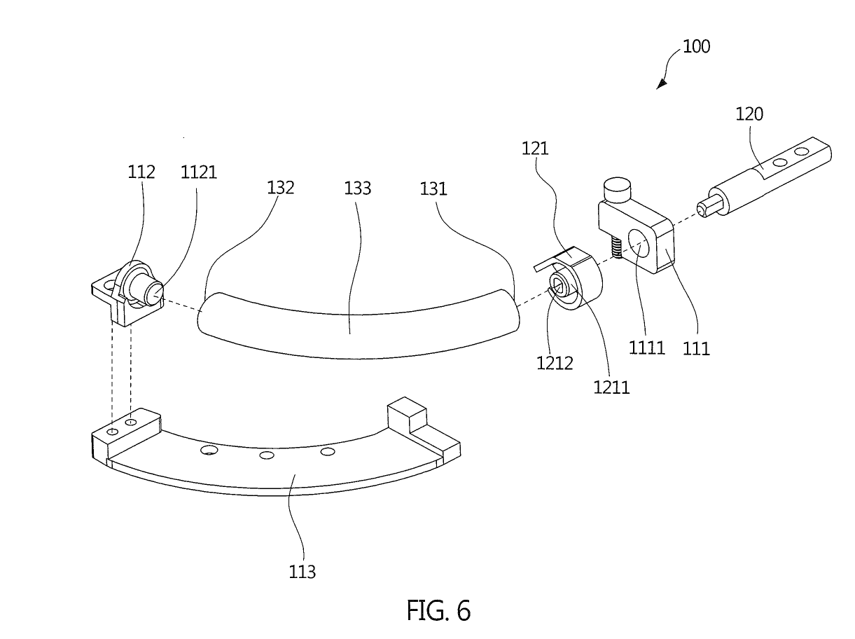

Please refer to FIG. 6. FIG. 6 illustrates an exploded view of the hinge 100 of FIG. 5 from another viewing angle according to an embodiment of the present invention.

In the embodiment, the pivoting portion 111 comprises an axial hole 1111. The axial hole 1111 has a circular cross section, and thus the shaft member 120 is rotatably disposed in the axial hole 1111. The bracket portion 121 is between the spring body 133 and the pivoting portion 111. In addition, the shaft member 120 comprises the bracket portion 121. The bracket portion 121 is coupled to an end of the shaft member 120, and the first end 131 is fixed to the bracket portion 121. Moreover, the bracket portion 121 comprises a first fixing column 1211. The first fixing column 1211 penetrates into the first end 131 of the spring body 130. The first end 131 surrounds and is fixed to the first fixing column 1211. For example, the first end 131 may enclose the first fixing column 1211 and may be tightly fitted on the first fixing column 1211. Further, the bracket portion 121 comprises an embedding hole 1212. The embedding hole 1212 has a non-circular cross section. An end of the shaft member 120 fits and is fixed in the embedding hole 121. Due to the non-circular cross section of the embedded hole 1212, the shaft member 120 drives the bracket portion 121 to rotate when the shaft member 120 rotates. In the embodiment, the embedded hole 1212 penetrates through the first fixing column 1211.

In the embodiment, the fixing portion 112 comprises a second fixing column 1121. The second fixing column 1121 penetrates into the second end 132. The second end 132 surrounds and is fixed to the second fixing column 1121. For example, the second end 132 may enclose the second fixing column 1121 and may be tightly fitted on the second fixing column 1121. In other embodiments, the first end 131 and the second end 132 may be respectively fixed to the bracket portion 121 and the fixing portion 112 in any known manners. For example, there may be arms respectively protruded from the first end 131 and the second end 132, and the arms may be respectively inserted into and fixed to corresponding holes on the bracket portion 121 and the fixing portion 112; alternatively, the arms may be respectively clamped and fixed by corresponding clamping mechanisms on the bracket portion 121 and the fixing portion 112.

Concisely, the present invention provides a hinge and an electronic device using the hinge. The hinge has a simple structure, which can lower the cost of manufacture of the hinge and the electronic device. Additionally, the hinge has better adaptability; therefore, the hinge can be utilized in electronic devices with special appearance, e.g., an electronic device with an arc-shaped edge.

While the present invention has been described by way of example and in terms of the preferred embodiments, it is to be understood that the present invention does not be limited to the disclosed embodiments. For anyone skilled in the art, various modifications and improvements within the spirit of the present invention are covered under the scope of the present invention. The covered scope of the present invention is based on the appended claims.

What is claimed is:

1. A hinge comprising:
a fixing member comprising a pivoting portion and a fixing portion, the pivoting portion and the fixing portion being respectively fixed to opposite ends of the fixing member;
a shaft member pivotably connected to the pivoting portion; and
a spring member comprising a spring body, a first end, and a second end, the spring body being between the first end and the second end, the first end being fixed to the shaft member, the second end being fixed to the fixing portion, wherein when the shaft member rotates, the shaft member drives the spring body to twist via the first end.

2. The hinge of claim 1, wherein the spring body is of an arc shape.

3. The hinge of claim 2, wherein the fixing member further comprises an arc plate, the pivoting portion and the fixing portion are respectively fixed to opposite ends of the arc plate, and the spring body is disposed corresponding to the arc plate.

4. The hinge of claim 1, wherein the shaft member comprises a bracket portion, the bracket portion is coupled to an end of the shaft member, and the first end is fixed to the bracket portion.

5. The hinge of claim 4, wherein the bracket portion comprises a first fixing column, the first fixing column penetrates into the first end, and the first end surrounds and is fixed to the first fixing column.

6. The hinge of claim 5, wherein the bracket portion comprises an embedding hole, the embedding hole has a non-circular cross section, and an end of the shaft member fits and is fixed in the embedding hole.

7. The hinge of claim 6, wherein the pivoting portion comprises an axial hole, the shaft member is rotatably disposed in the axial hole, and the bracket portion is between the spring body and the pivoting portion.

8. The hinge of claim 1, wherein the fixing portion comprises a second fixing column, the second fixing column penetrates into the second end, and the second end surrounds and is fixed to the second fixing column.

9. An electronic device comprising:
a hinge comprising:
a fixing member comprising a pivoting portion and a fixing portion, the pivoting portion and the fixing portion being respectively fixed to opposite ends of the fixing member;
a shaft member pivotably connected to the pivoting portion; and
a spring member comprising a spring body, a first end, and a second end, the spring body being between the first end and the second end, the first end being fixed to the shaft member, the second end being fixed to the fixing portion, wherein when the shaft member rotates, the shaft member drives the spring body to twist via the first end;
a first plate, wherein the shaft member of the hinge is fixed to the first plate; and
a second plate, wherein the fixing member of the hinge is fixed to the second plate.

10. The electronic device of claim 9, wherein an edge of the second plate is of an arc shape and the spring body is disposed corresponding to the arc-shaped edge.

11. The electronic device of claim 9, wherein the spring body is of an arc shape.

12. The electronic device of claim 11, wherein the fixing member further comprises an arc plate, the pivoting portion and the fixing portion are respectively fixed to opposite ends of the arc plate, and the spring body is disposed corresponding to the arc plate.

13. The electronic device of claim 9, wherein the shaft member comprises a bracket portion, the bracket portion is coupled to an end of the shaft member, and the first end is fixed to the bracket portion.

14. The electronic device of claim 13, wherein the bracket portion comprises a first fixing column, the first fixing column penetrates into the first end, and the first end surrounds and is fixed to the first fixing column.

15. The electronic device of claim 14, wherein the bracket portion comprises an embedding hole, the embedding hole has a non-circular cross section, and an end of the shaft member fits and is fixed in the embedding hole.

16. The electronic device of claim 15, wherein the pivoting portion comprises an axial hole, the shaft member is rotatably disposed in the axial hole, and the bracket portion is between the spring body and the pivoting portion.

17. The electronic device of claim 9, wherein the fixing portion comprises a second fixing column, the second fixing column penetrates into the second end, and the second end surrounds and is fixed to the second fixing column.
